(19) United States
(12) Patent Application Publication
(10) Pub. No.: US 2010/0044709 A1
(43) Pub. Date: Feb. 25, 2010

(54) THIN FILM TRANSISTOR, MANUFACTURING METHOD THEREOF AND DISPLAY DEVICE

(75) Inventors: Tetsuo Nakayama, Tokyo (JP); Toshiaki Arai, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/303,287

(22) PCT Filed: Mar. 19, 2008
(86) PCT No.: PCT/JP2008/055044

§ 371 Date: Dec. 3, 2008

(30) Foreign Application Priority Data
Apr. 4, 2007 (JP) 2007-098026

(51) Int. Cl. H01L 33/00; H01L 29/786; H01L 21/336

(52) U.S. Cl. 257/59; 257/57; 438/158; 257/E21.414; 257/E29.291; 257/E33.053

(57) ABSTRACT

A thin film transistor is formed by laminating a gate electrode 3, a gate insulating film(4), a channel layer(5), and source/drain layers(7),(8) on a substrate(2) in this order or in a reversed order thereof. The thin film transistor is characterized in that the source/drain layers(7), (8) contain impurities having a concentration gradient such that a concentration becomes lower toward the channel layer(5). The thin film transistor which can increase an on/off ratio, manufacture method thereof, and a display device are provided.

### TECHNICAL FIELD

The present invention relates to a thin film transistor, manufacture method thereof and a display device, and particularly to a thin film transistor suitably used for driving a current drive type element, such as an organic EL element, its manufacture method and a display device.

### BACKGROUND ART

In recent years, attentions are paid to a display device for displaying an image by utilizing an organic EL (electro luminescence) phenomenon as one of flat panel displays. This display device, i.e., an organic EL display, has excellent characteristics, such as a broad viewing angle and a low consumption power, because an emission phenomenon of an organic emission element itself is used. Further, since a high response is showed to a high-definition high speed video signal, developments are progressing for practical applications, especially in a video field.

Out of driving systems of an organic EL display, an active matrix system using a Thin Film Transistor (TFT) driving element is superior compared to a conventional passive matrix system, in terms of response and resolution, and is considered to be a driving system particularly suitable for an organic EL display having the above-described characteristics.

An organic EL display of an active matrix system has a drive panel provided with at least organic emission elements (organic EL elements) having organic emission material and drive elements (thin film transistors (TFT)) for driving the organic emission elements. The organic EL display has a configuration in which this drive panel and a sealing panel are bonded together through an adhesion layer in a manner sandwiching the organic emission elements.

As thin film transistors constituting an organic EL display of an active matrix type, at least a switching transistor for controlling bright and dark of a pixel and a drive transistor for controlling emission of an organic EL element are required.

In a thin film transistor, it is known that a threshold voltage shifts if a state where a voltage is applied to a gate electrode of the thin film transistor continues. However, a drive transistor of the organic EL display is required to maintain the electric conduction state as long as the organic EL element is caused to emit light, and a threshold shift is likely to occur. If the threshold voltage of a drive transistor shifts, a current amount flowing in the drive transistor varies, and consequently a luminance of an emission element constituting each pixel changes.

An organic EL display is under development in recent years which uses a drive transistor having a channel region configured of a semiconductor layer of crystalline silicon in order to reduce a threshold shift of the drive transistor.

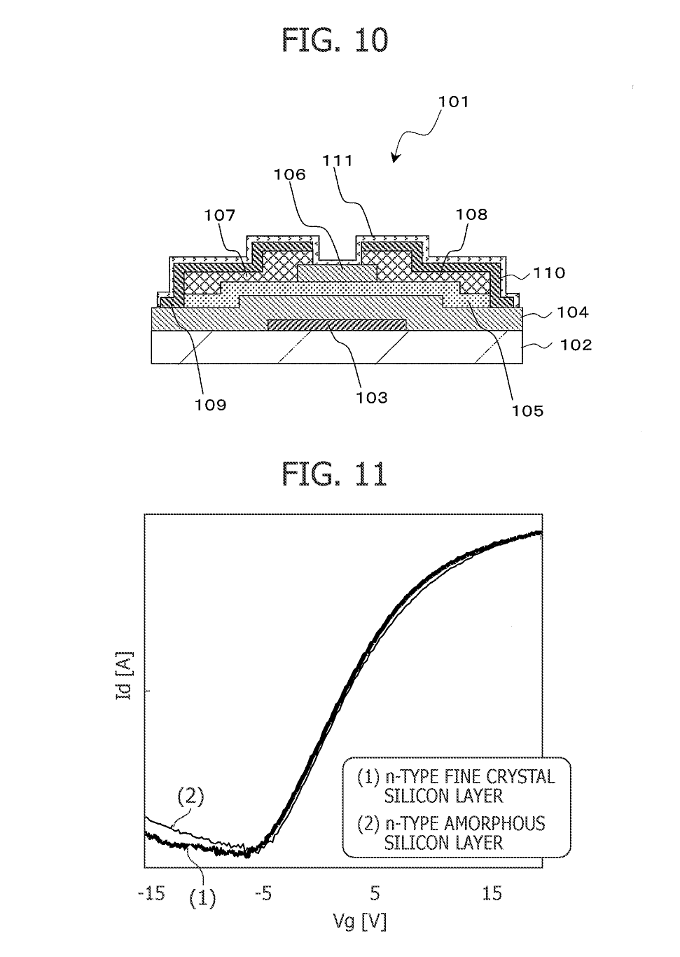

An example of the structure of a thin film transistor used for an organic electric field emission element of an active matrix system is herein shown in FIG. 10. A thin film transistor 101 shown in this drawing is a thin film transistor of an n-channel type (n-type) of a bottom gate type, and a gate insulating film 104 made of silicon nitride is formed in a state covering a gate electrode 103 pattern-formed on a substrate 102 made of glass or the like. A channel layer 105 made of amorphous silicon or fine crystal silicon is pattern-formed on this gate insulating film 104 in a state covering the gate electrode 103.

Further, a channel protective layer 106 is arranged on the above-described channel layer 105 above the central region of the gate electrode 103. Then, a source layer 107 and a drain layer 108 are pattern-formed on the above-described channel layer 105 in a mutually separated state, such that above both end portions of the channel protective layer 106 are covered. Furthermore, a source electrode 109 and a drain electrode 110 are pattern-formed on the gate insulating film 104, and a part of the source electrode and a part of the drain electrode are stacked on the source layer 107 and the drain layer 108, respectively. In a state a whole surface area of the substrate 102 in this state is covered, a passivation film 111 is provided.

In the thin film transistor as described above, an n-type amorphous silicon layer or an n-type fine crystal silicon layer containing n-type impurities is widely used as the source/drain layers 107 and 108. Herein, measurement results of current-voltage characteristics when single layers of an amorphous silicon layer and a fine crystal silicon layer are used for the source/drain layers 107 and 108, respectively are shown in FIG. 11.

As shown in this graph, it can be understood that the thin film transistor using the n-type fine crystal silicon layer as the source/drain layers 107 and 108 has a lower off-current and more excellent off-characteristics than the transistor using the n-type amorphous silicon layer, and the thin film transistor using the n-type amorphous silicon layer for the source/drain layers 107 and 108 has a higher on-current and more excellent on-characteristics than the transistor using the n-type fine crystal silicon layer.

Therefore, attempts for making the on-characteristics and off-characteristics compatible are made by combining the n-type fine crystal silicon layer having the excellent off-characteristics and the n-type amorphous silicon layer having the excellent on-characteristics. For example, there is a report on an example of a thin film transistor in which the source/drain layers 107 and 108 (ohmic contact layers) are configured by two layers of an n-type fine crystal silicon layer and an n-type amorphous silicon layer, and an n-type amorphous silicon layer is arranged on the channel layer side (for example, refer to Japanese Patent Application Publication No. JP HEI 8-172195). However, this thin film transistor has a higher off-current than a case where the n-type fine crystal silicon layer or n-type amorphous silicon layer are used as a single layer, and a sufficient on-current cannot be obtained.

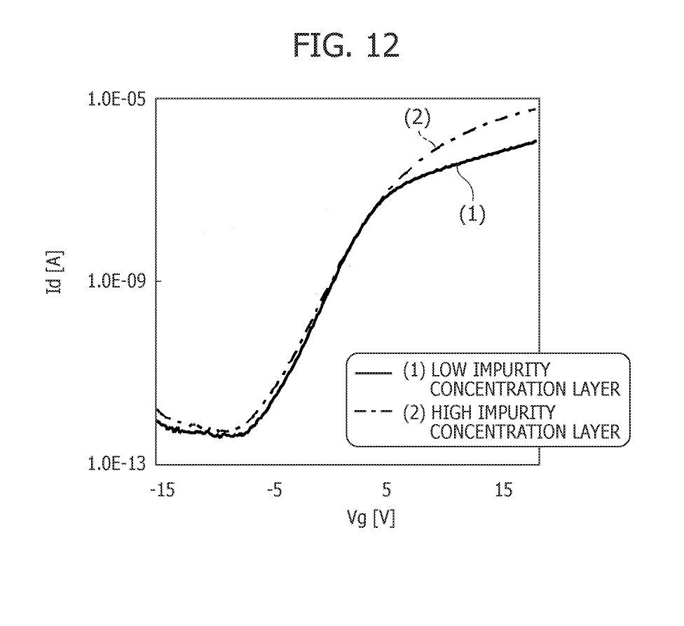

Therefore, by paying attention to impurity concentrations of the source/drain layers 107 and 108, a graph of measurements of gate voltage (Vg)—drain current (Id) characteristics (Vds=+10 V) of two thin film transistors provided with source/drain layers having different impurity concentrations (phosphorous concentrations) is shown in FIG. 12. A graph (1) is a graph of a thin film transistor having source/drain layers at a phosphorous concentration of 1.9×10²⁰/cm³ (assumed as low impurity concentration layers) and a graph (2) is a graph of a thin film transistor having source/drain layers at a phosphorous concentration of 3.9×10²¹/cm³ (assumed as high impurity concentration layers).

### DISCLOSURE OF THE INVENTION

However, as shown in the graph of FIG. 12, the thin film transistor (1) in which a phosphorous concentration of the source/drain layers 107 and 108 is low has a lower off-current as compared to the thin film transistor having a high phosphorous concentration, and although the off-characteristics are excellent, an on-current is also low and the on-characteristics are not sufficient. Therefore, if this thin film transistor is used as a display element, a sufficient switching operation cannot be performed. Further, if this thin film transistor is used as a drive transistor, there is a concern that a drive current may be lowered and there is a possibility that a display quality may be lowered seriously. On the other hand, the thin film transistor (2) in which a phosphorous concentration of the source/drain layers 107 and 108 is high has a higher on-current as compared to the thin film transistor having a low phosphorous concentration, and although the on-characteristics are excellent, an off-current is also high and the sufficient off-characteristics cannot be obtained. Therefore, if this thin film transistor is used as a display element, a leak current becomes large, and there is a possibility that a display quality may be lowered seriously. In this way, there is a tradeoff relation between the on-characteristics and off-characteristics, and it is difficult to make the both characteristics compatible.

From the reasons described above, the present invention aims to provide a thin film transistor having a high on/off ratio, manufacture method thereof and a display device.

In order to achieve the object as described above, a thin film transistor of the present invention which is formed by laminating a gate electrode, a gate insulating film, a channel layer, and source/drain layers on a substrate in this order or in an reversed order thereof, is characterized in that the source/drain layers are constituted of a silicon layer containing impurities in a manner a channel layer side becomes lower in concentration than the other.

According to the thin film transistor of this type, the source/drain layers are constituted of a silicon layer containing impurities in a manner a concentration on a channel layer side becomes lower than the other, and accordingly, as is described in detail in the embodiments of the present invention, it is confirmed that as an off-current is lowered, an on-current is increased also and an on/off ratio is increased, as compared to a thin film transistor whose impurity concentrations of the source/drain layers are constant at a high or low concentration which was described in the background art.

Furthermore, the present invention is also a manufacture method of the thin film transistor of this type in which a gate electrode, a gate insulating film, a channel layer, and source/drain layers are stacked on a substrate in this order or in an reversed order thereof, and the manufacture method of the thin film transistor is characterized in that characteristics of the thin film transistor are controlled by impurity concentrations of the source/drain layers.

According to the manufacture method of the thin film transistor of this type, since the characteristics of the thin film transistor are controlled by impurity concentrations of the source/drain layers, a thin film transistor is formed which has a structure having the source/drain layers constituted of a silicon layer containing impurities, for example, in a manner a concentration on a channel layer side becomes lower than the other.

Further, the present invention is also a display device having the above-described thin film transistor, and the display device is made by arranging and forming the thin film transistor having a gate electrode, a gate insulating film, a channel layer, and source/drain layers stacked on a substrate in this order or in an reversed order thereof, and a display element connected to the thin film transistor. The display device is characterized in that the source/drain layers are constituted of a silicon layer containing impurities such that a concentration on a channel layer side becomes lower than the other.

According to the display device of this type, since the above-described thin film transistor is provided, as an off-current is reduced, an on-current is increased also, whereby an on/off ratio is increased.

As described above, according to the thin film transistor and the display device having this thin film transistor of the present invention, as an off-current is reduced, an on-current is increased also, and an on/off ratio is increased, whereby due to the reduction of the off-current, a leak current is suppressed. Further, due to the increase of the on-current, a sufficient switching operation can be obtained and also a drive current can be increased, whereby a carrier mobility can be improved. Therefore, while the electrical characteristics of a thin film transistor can be improved, high performance of the display device can be aimed also.

Further, according to the manufacture method of a thin film transistor of the present invention, it is possible to obtain a thin film transistor having an increased on/off ratio, compared to a thin film transistor whose impurity concentrations of the source/drain layers, which are described in the background art, are constant at a high concentration or a low concentration.

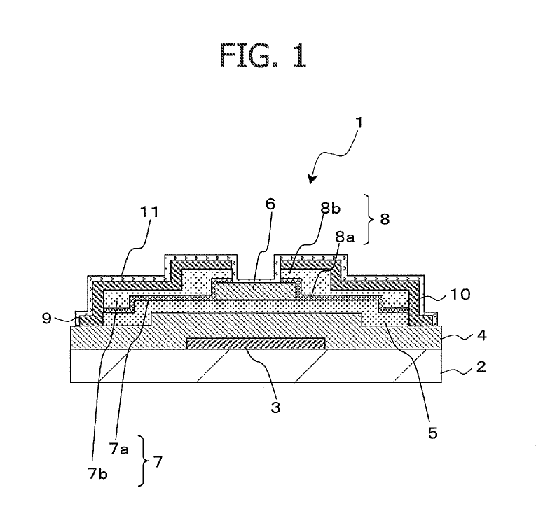

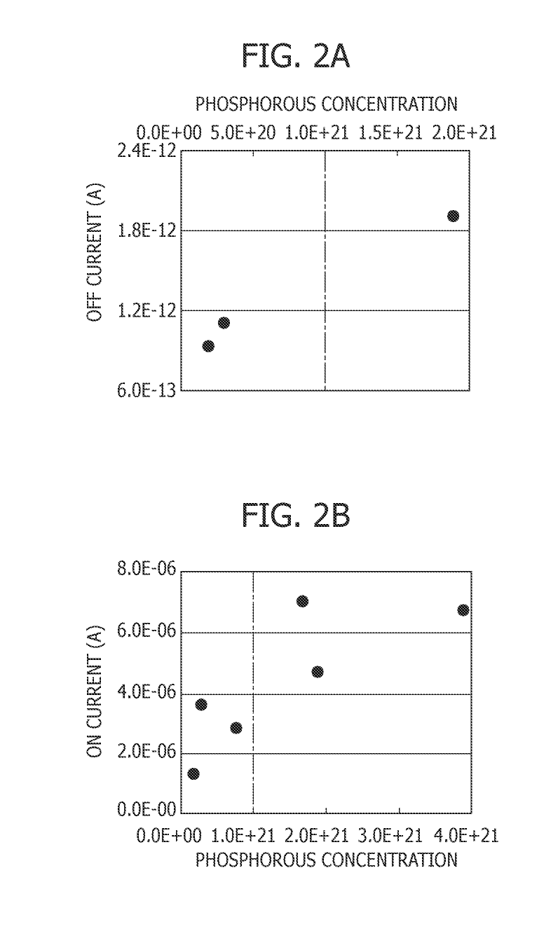

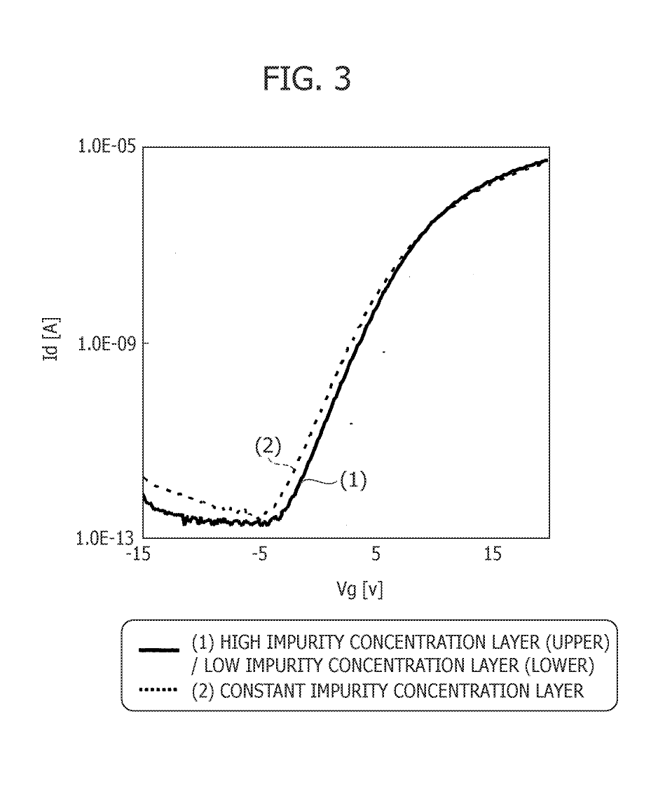

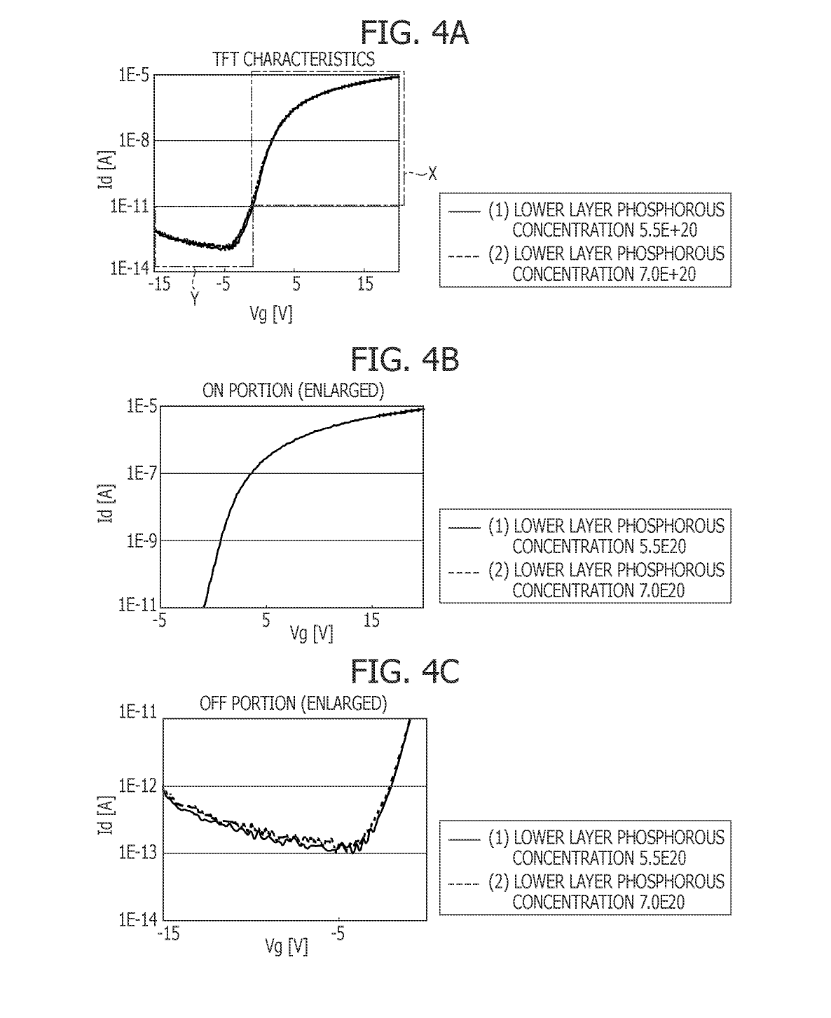

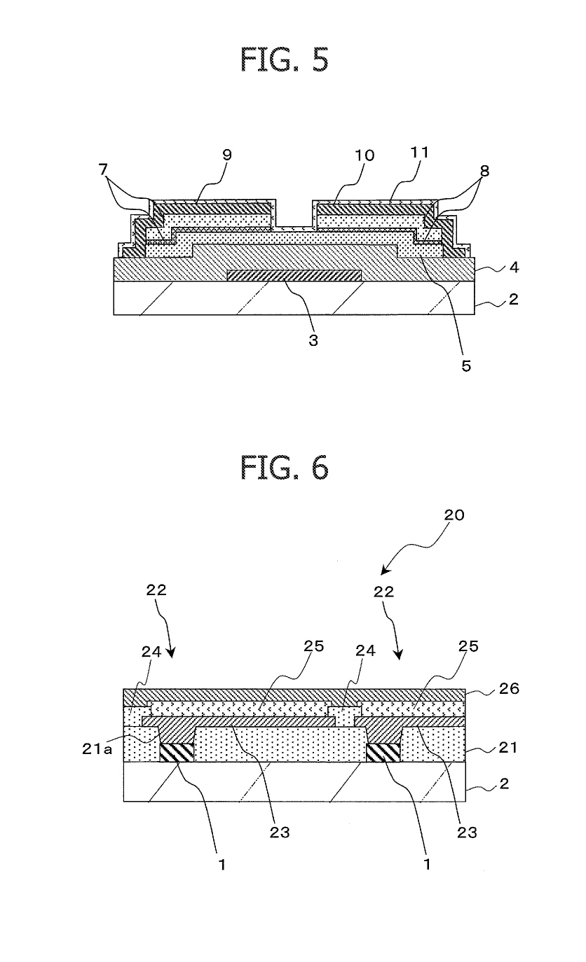

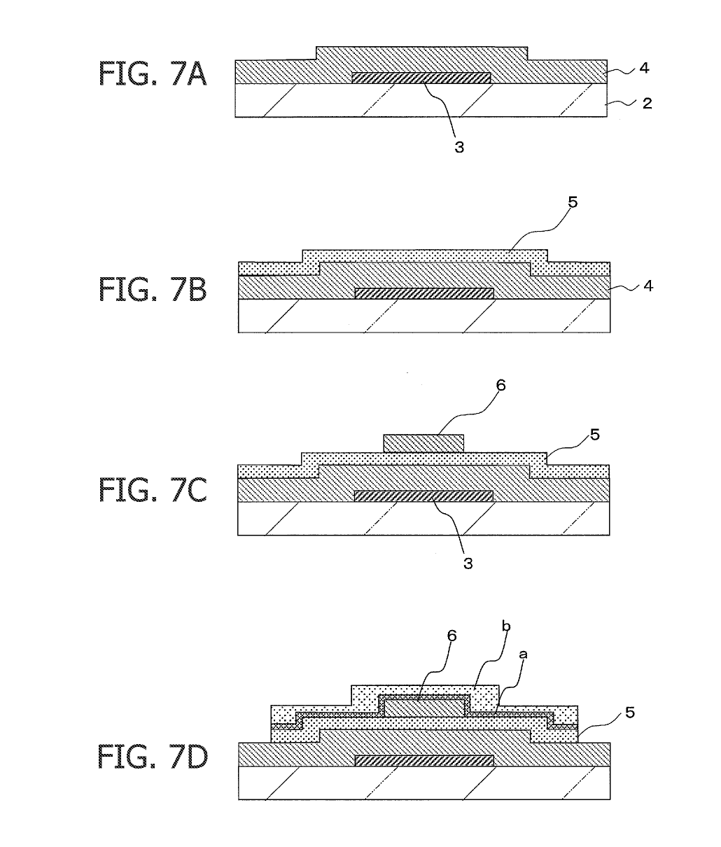

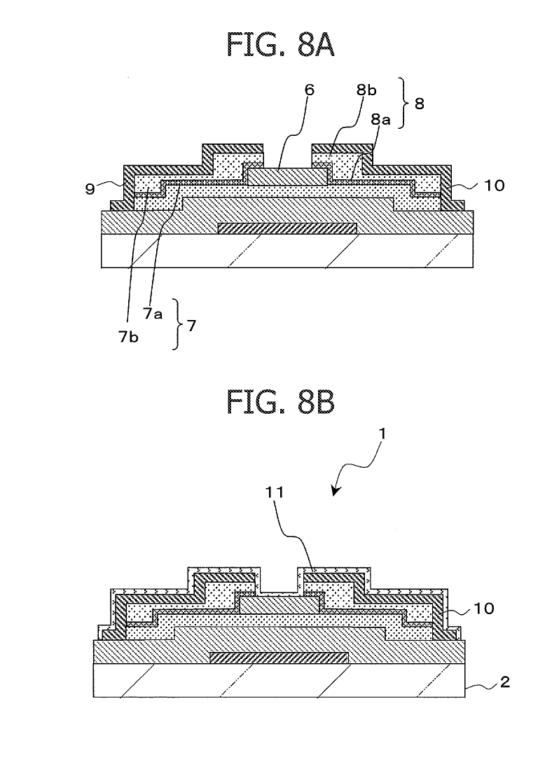

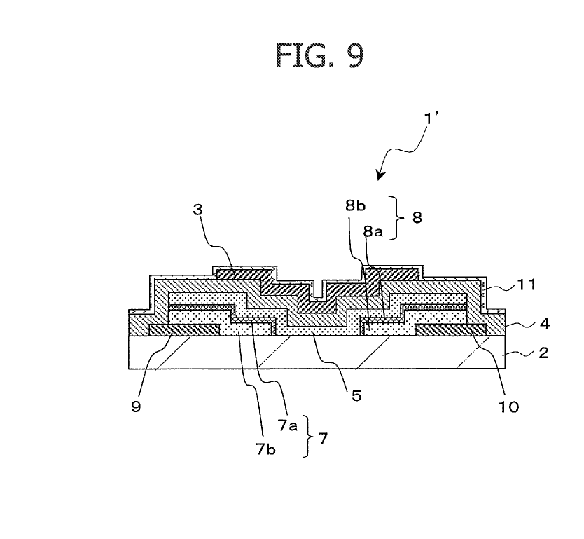

### BRIEF DESCRIPTION OF THE DRAWINGS

[FIG. 1] A cross sectional view showing the structure of a thin film transistor according to a first embodiment of the present invention.

[FIG. 2] Graphs obtained by measuring off-currents (a) and on-currents (b) of thin film transistors provided with source/drain layers having different phosphorous concentrations.

[FIG. 3] A graph showing current—voltage characteristics of the thin film transistor according to the first embodiment of the present invention.

[FIG. 4] A graph (a) shows current—voltage characteristics of the thin film transistor according to the first embodiment of the present invention, an enlarged diagram (b) shows an on-portion, and an enlarged diagram (c) shows an off-portion.

[FIG. 5] A cross sectional view showing another example of a thin film transistor according to the first embodiment of the present invention.

[FIG. 6] A cross sectional view showing the structure of a display device provided with the thin film transistor of the first embodiment of the present invention.

[FIG. 7] Manufacturing-process cross sectional views (part 1) showing manufacturing method of a thin film transistor according to the first embodiment of the present invention.

[FIG. 8] Manufacturing-process cross sectional views (part 2) showing manufacturing method of the thin film transistor according to the first embodiment of the present invention.

[FIG. 9] A cross sectional view showing the structure of a thin film transistor according to a second embodiment of the present invention.

[FIG. 10] A cross sectional view showing the structure of a conventional thin film transistor.

[FIG. 11] A graph showing current—voltage characteristics of thin film transistors in a case where a fine crystal silicon layer and an amorphous silicon layer are used for source/drain layers, respectively.

[FIG. 12] A graph showing current—voltage characteristics of thin film transistors in a case where a high impurity concentration layer and a low impurity concentration layer are used for source/drain layers, respectively.

### BEST MODE FOR CARRYING OUT THE INVENTION

Embodiments of the present invention are described in detail below.

### FIRST EMBODIMENT

FIG. 1 is a cross sectional structural view for explaining a thin film transistor of a first embodiment. A thin film transistor 1 shown in this drawing is a thin film transistor of an n-type of a bottom gate type. A strip-shaped gate electrode 3 formed of, e.g., molybdenum is, pattern-formed on a substrate 2 made of an insulating substrate, such as glass. This gate electrode 3 is not particularly limited, even if material is other than molybdenum, as long as the material is refractory metal hard to be altered by heat which is caused when a crystallization process is performed.

A gate insulating film 4 made of, e.g., a silicon oxide film, is also formed in a state covering the gate electrode 3. In addition to the silicon oxide film, this gate insulating film 4 is constituted of a silicon nitride film, a silicon oxynitride film, or a lamination film of these.

Further, a channel layer 5 made of, e.g., amorphous silicon, is pattern-formed on this gate insulating film 4 in a state of covering the gate electrode 3. Noted, the channel layer 5 may be constituted of fine crystal silicon, and a channel protective layer 6 made of insulating material, such as a silicon nitride film is provided on the channel layer 5 above the gate electrode 3. In a manufacture method which is described later, this channel protective layer 6 functions as an etching stopper layer when pattern-forming source/drain layers, which are formed on an upper layer of the channel protective layer 6, by etching, and since the channel protective layer 6 is provided, the channel layer 5 is prevented from being corroded by the above-described etching. As the channel protective layer 6, in addition to the above-described silicon nitride film, a silicon oxide film, a silicon oxynitride film, or a lamination film of these is used.

Further, a part of a source layer 7 and a part of a drain layer 8 are stacked on both end portions of the above-described channel protective layer 6, and the source layer and the drain layer are pattern-formed on the channel layer 5 in a mutually separated state. Furthermore, as the characteristic structure of the present invention, the source/drain layers 7 and 8 contain impurities at a concentration gradient in a manner a concentration becomes lower toward the channel layer 5. As the impurities described above, it is assumed that n-type impurities made of, e.g., phosphorous, are used. However, the n-type impurities are not limited to the above, but may be other elements of V group.

It is herein assumed that the source/drain layers 7 and 8 are constituted of a two-layer structure in which first silicon layers 7a and 8a and second silicon layers 7b and 8b having an impurity concentration higher than that of the first silicon layers 7a and 8a are sequentially laminated from the channel layer 5 side. Hence, it becomes a state where the first silicon layers 7a and 8a having a low impurity concentration are arranged at the channel layer 5 side. By configuring the source/drain layers 7 and 8 as described above, it was confirmed, as is later described, that an off-current of the thin film transistor becomes low and an on-current increases as compared to a thin film transistor having source/drain layers containing impurities at a constant concentration. As a result, it was suggested that the off-characteristics of the thin film transistor are controlled by the first silicon layers 7a and 8a containing n-type impurities of a low concentration and arranged at the channel layer 5 side and that the on-characteristics of the thin film transistor are controlled by the second silicon layers 7b and 8b containing n-type impurities of a high concentration and arranged at the side of source/drain electrodes 9 and 10 side.

Here, FIGS. 2(a) and 2(b) show graphs which indicate measurements of off-currents and on-currents of thin film transistors provided with source/drain layers having different phosphorous concentrations. For example, conversion is made for an on-current in a case where a phosphorous concentration is 1×10²¹/cm³ by applying to the graph, then an on-current is 3.0×10⁻⁶ A and an-off current is 1.4×10⁻¹² A, and consequently, a TFT element having an on/off ratio of about 2.1×10⁶ can be obtained. A TFT element having a higher on/off ratio can be obtained if a phosphorous concentration of the first silicon layers 7a and 8a is set to be not higher than 1×10²¹/cm³ and if a phosphorous concentration of the second silicon layers 7b and 8b is set to be higher than 1×10²¹/cm³.

The phosphorous concentrations of the first silicon layers 7a and 8a and the second silicon layers 7b and 8b may be selected in accordance with a desired TFT element if the first silicon layers 7a and 8a have a concentration lower than that of the second silicon layers 7b and 8b, and are not required to be specifically defined. However, in general, the off-characteristics not larger than about 1.0×10⁻¹² A are required in order to prevent a display quality from being lowered, and it is desired, from the conversion made from the graph of FIG. 2(a), that a phosphorous concentration of the first silicon layers 7a and 8a is not higher than 2.0×10¹²/cm³.

Furthermore, as described in the background art, since the fine crystal silicon layer has more excellent off-characteristics than the amorphous silicon layer and the amorphous silicon layer has more excellent on-characteristics than the fine crystal silicon layer, it is more preferable that the first silicon layers 7a and 8a are constituted of the fine crystal silicon layer and the second silicon layers 7b and 8b are constituted of the amorphous silicon layer. This also improves the on/off ratio.

On the other hand, the source electrode 9 and the drain electrode 10 are pattern-formed on the gate insulating film 4 in a state a part of the source electrode and a part of the drain electrode are stacked on the source layer 7 and the drain layer 8 which have the above-described structure, respectively. A passivation film 11 is provided in a state of covering a whole surface area of the substrate 2 of this state.

FIG. 3 shows herein measurement results of gate voltage (Vg)—drain current (Id) characteristics (Vds=+10 V) with respect to the thin film transistor having the above-described structure.

Herein, a graph (1) shows the measurement results of the thin film transistor having the source/drain layers 7 and 8 of a two-layer structure in which the first silicon layers 7a and 8a having a phosphorous concentration of 1.9×10²⁰/cm³ are arranged on the channel layer 5 side (lower portion side) and the second silicon layers 7b and 8b having a phosphorous concentration of 3.9×10²¹/cm³ are arranged on the side of the source/drain electrodes 9 and 10 (upper portion side), as explained in the above-described embodiment. In this thin film transistor, the first silicon layers 7a and 8a are formed by having a film thickness of 50 nm and the second silicon layers 7b and 8b are formed by having a film thickness of 50 nm.

Further, a graph (2) is the measurement results of a thin film transistor in which the source/drain layers 7 and 8 are formed at a phosphorous concentration of 1.9×10²¹/cm³ and at a film thickness of 100 nm.

Noted, for measurement of drain current values of each thin film transistor, the drain current values were monitored while continuously shifting a gate voltage to a minus direction and a plus direction.

First, it was confirmed from the graphs (1) and (2) of FIG. 3 that as compared to the measurement results of (2) the thin film transistor which includes the source/drain layers having a high and constant phosphorus concentration, to which the present invention is not applied, the measurement results of (1) the thin film transistor to which the present invention is applied indicate that while the off-current is reduced, the on-current is increased. Hence, it was confirmed that the thin film transistor of (1) has an increased on/off ratio as compared to the thin film transistor of (2).

FIG. 4(a) shows also measurement results of gate voltage (Vg)—drain current (Id) characteristics (Vds=+10 V) of another thin film transistor having the above-described structure. Further, FIG. 4(b) is an enlarged view of an on-portion X of the graph of FIG. 4(a), and FIG. 4(c) is an enlarged view of an off-portion Y of the graph of FIG. 4(a).

Both the graphs (1) and (2) in FIG. 4 show the measurement results of thin film transistors having the source/drain layers 7 and 8 made of a lamination of silicon layers having different phosphorous concentrations described in the above-described embodiment. In the graphs (1) and (2), a silicon layer having a phosphorous concentration of 1.7×10²¹/cm³ is arranged for the second silicon layers 7b and 8b on the side (upper portion side) of the source/drain electrodes 9 and 10.

The first silicon layers 7a and 8a having a phosphorous concentration of 5.5×10²⁰/cm³ are arranged at the channel layer 5 side (lower portion side) in the graph (1), and the first silicon layers 7a and 8a having a phosphorous concentration of 7.0×10²⁰/cm³ are arranged at the channel layer 5 side (lower portion side) in the graph (2). In these thin film transistors, the first silicon layers 7a and 8a are formed by having a film thickness of 50 nm and the second silicon layers 7b and 8b are formed by having a film thickness of 50 nm.

Noted, for measurement of drain current values of each thin film transistor, the drain current values were monitored while continuously shifting a gate voltage to a minus direction and a plus direction.

As shown in FIG. 4(b), in the thin film transistors shown in the graphs (1) and (2), since the second silicon layers 7b and 8b have the same phosphorous concentration, the on-current is the same at 8.0×10⁻⁶ (A). On the other hand, since the thin film transistors shown in the graphs (1) and (2) have different phosphorous concentrations of the first silicon layers 7a and 8a, a difference is appeared in the off-characteristics. Namely, the phosphorous concentrations of the first silicon layers are 5.5×10²⁰/cm³ for (1) and 7.0×10²⁰/cm³ for (2), thereby having a relation of (1)<(2). Consequently, the off-currents are 8.7×10⁻¹⁴ (A) in the graph (1) and 1.0×10⁻¹³ (A) in the graph (2), indicating (1)<(2) by corresponding to amounts of the phosphorous concentrations.

According to the measurement results of these thin film transistors, the off-current can be reduced in correspondence with the phosphorous concentrations intended by the present invention, as a result, the thin film transistor of (1) has an increased on/off ratio as compared to the thin film transistor of (2).

As above, according to the thin film transistor of the present embodiment, as an off-current is reduced, an on-current is increased also, and the on/off ratio is increased. Therefore, as the off-current is reduced, a leak current is suppressed, and as the on-current is increased, a sufficient switching operation can be obtained, whereby a drive current can be increased and a carrier mobility can be improved. Accordingly, the electrical characteristics of a thin film transistor can be improved.

Further, according to the present embodiment, by controlling a phosphorous concentration, the characteristics of a TFT element can be controlled as desired, and increase of the on-characteristics and reduction of the off-characteristics can be controlled independently. As a result, the degree of freedom on process can be made large and merits of the present invention are large.

Noted, herein, although description was made on an example that the source/drain layers 7 and 8 are constituted of a two-layer structure formed of the first silicon layers 7a and 8a and the second silicon layers 7b and 8b containing impurities at a concentration higher than that of the first silicon layers 7a and 8a, the present invention is not limited thereto, but the source/drain layers 7 and 8 may be constituted of three or more layers if n-type impurities are contained by having a concentration gradient in which a concentration becomes lower toward the channel layer 5. Further, a single layer structure may be also possible which contains impurities having a concentration gradient in which a concentration becomes continuously lower toward the channel layer 5.

Furthermore, in the above-described embodiment, although description was made on the example in which the channel protective layer 6 is provided on the channel layer 5 above the gate electrode 3, the present invention is applicable even in a case where the channel protective layer 6 (refer to FIG. 1) is not provided as shown in FIG. 5. In this case, the passivation film 11 is provided in a state of covering not only the source/drain electrodes 9 and 10 but also the channel layer 5. It is, however, preferable to provide the channel protective layer 6, because corrosion of the channel layer 5 can be prevented. The corrosion is caused by etching performed when pattern-forming the source/drain electrodes 9 and 10 and source/drain layers 7 and 8 by etching.

Next, with reference to FIG. 6, description is made on an example of a structure of a display device using the thin film transistor 1 of this type, by using an organic EL display as an example. Noted, illustration of the detailed structure of the thin film transistor 1 in the drawing is omitted in FIG. 6.

A display device 20 is constituted by arranging and forming light emitting elements (in this example, organic EL element) 22 connected to the respective thin film transistors 1 on an interlayer insulating film 21 which covers surface sides of the substrate 2 where the thin film transistors 1 are formed. Each organic EL element 22 has a lower electrode 23 connected to the thin film transistor 1 via a connection hole 21a formed in the interlayer insulating film 21. These lower electrodes 23 are patterned per each pixel in a state that the peripheral areas of the lower electrodes are covered with an insulating film pattern 24 and only a central area is widely exposed. Further, an organic layer 25 having at least a light emitting layer is laminated on the exposed portion of each lower electrode 23 in a patterned state. This light emitting layer is assumed to be made of organic material which causes emission of light by recombination of holes and electrons injected into the light emitting layer, and an upper electrode 26 is arranged and formed above each thus patterned organic layer 25 and the insulating film pattern 24, in a state where insulation is kept between the lower electrodes 23.

In this display device 20, the lower electrode 23 is used as an anode (or a cathode) and the upper electrode 26 is used as a cathode (or an anode). Then, holes and electrons are injected from the lower electrodes 23 and the upper electrode 26 to the organic layer 25 which is sandwiched between the lower electrodes 23 and the upper electrode 26, whereby light emission is caused in the portion of the light emitting layer of the organic layer 25. It is to be noted that if this display device 20 is an upper surface emission type in which emission light is extracted from the upper electrode 26 side, the upper electrode 26 is assumed to be structured by using material having high light transmission property. On the other hand, if this display device 20 is a transmission type in which emission light is extracted from the substrate 2 side, the substrate 2 and the lower electrodes 23 are assumed to be structured by using materials having high light transmission property.

According to the display device 20 having this type of structure, since it is structured as the thin film transistor 1 having the structure described with reference to FIG. 1 is connected to the organic EL element 22, the on/off ratio of the thin film transistor 1 can be increased, and the carrier mobility can be improved as well. It is therefore possible to aim high performance of the display device.

Further, although illustration is omitted in this drawing, a pixel circuit in the display device 20 using the organic EL element 22 requires a switching transistor for one pixel and a drive transistor for controlling light emission of the organic EL element 22. At least two are required. Of these, if an off current of the drive transistor is not reduced, unevenness of luminance occurs and an image quality becomes degraded. However, as described above, since an off-current is reduced in the thin film transistor 1 used as this drive TFT, it becomes possible to aim evenness of image qualities in the display screen.

It is to be noted, herein, although the organic EL display is used as an example of the display device 20 in the description, the display device 20 is not limited to the organic EL display but, for example, may be a liquid crystal display display. However, it is preferable to use the above-described thin film transistor particularly for the drive transistor of the organic EL display, because the above-described effects can be obtained.

### <Manufacture Method>

Next, description is made on a manufacture method of the thin film transistor 1 having the structure described above and a manufacture method of a following display device.

First, as shown in FIG. 7(a), a molybdenum film having a film thickness of 100 nm is formed on the substrate 2 made of an insulating substrate, for example, by a sputtering method, and the gate electrode 3 is pattern-formed by performing normal photolithography and etching. Thereafter, the gate insulating film 4 made of a silicon oxide film is formed on the substrate 2 at a film thickness of e.g., 290 nm by a plasma CVD method, such that the gate insulating film 4 covers the gate electrode 3.

Next, as shown in FIG. 7(b), the channel layer 5 made of, e.g., amorphous silicon, is formed on the gate insulating film 4 at a film thickness of 30 nm. Noted, if a fine crystal silicon layer is used as the channel layer 5, fine crystallization may be performed by a method, such as laser anneal, for example, after the amorphous silicon layer is formed.

Next, as shown in FIG. 7(c), a silicon nitride film is formed at a film thickness of 200 nm on the gate insulating film 4 in a state of covering the channel layer 5. The channel protective layer 6 which covers above the gate electrode 3 is pattern-formed on the channel layer 5, by performing normal photolithography and etching. As this etching, for example, wet etching using solution which is made of hydrofluoric acid may be performed.

Next, a first silicon layer a containing n-type impurities constituted of phosphorous and a second silicon layer b containing n-type impurities at a concentration higher than that of the first silicon layer a are laminated and formed on the channel layer 5 in this order, in a state of covering the channel protective layer 6. In this case, the first silicon layer a and the second silicon layer b are continuously formed, for example, by a plasma CVD method using monosilane and hydrogen as film forming gas and using phosphine as n-type impurities. Hence, after the first silicon layer a is formed, discharge is once stopped and gas flow amounts of, e.g., phosphine is increased, whereby the second silicon layer b having a higher phosphorous concentration than that of the first silicon layer a can be formed continuously. It is to be noted that film forming parameters other than the gas flow amounts, such as a pressure and a discharge power, are assumed to be set as appropriate.

Here, film thicknesses of the above-described n-type fine crystal silicon layer a and the n-type amorphous silicon layer b can be controlled by a film forming apparatus. It is sufficient if the films have thicknesses approximately allowing formation of films with good coverage property, e.g., not thinner than 10 nm, and in here, for example, it is assumed that the first silicon layer a is 50 nm and the second silicon layer b is 50 nm.

Here, for example, in order to set a phosphorous concentration to around 1.0×10²¹/cm³, a flow amount ratio of phosphine (PH₃)/hydrogen (H₂) (dilution rate of 1 vol %) and monosilane (SiH₄) may be arranged to be around 0.01. Further, even if the ratio is the same, there is a case that a phosphorous concentration varies depending on total gas amounts of phosphine and monosilane, therefore it is necessary to select gas flow amounts as appropriate. Still further, in a case where the fine crystal silicon layer is used for the first silicon layer a and the amorphous silicon layer is used for the second silicon layer b, it is more preferable in that when the first silicon layer a of the fine crystal silicon layer is film-formed, a flow amounts ratio of hydrogen with respect to monosilane is set to be larger as compared to film forming conditions of the second silicon layer b constituted of the amorphous silicon layer, whereby fine crystallization becomes easy.

Further, in a case where the continuous film formation of this type is performed, control may be performed such that an impurity concentration is continuously changed from the first silicon layer a to the second silicon layer b. As a result, a silicon layer is formed which contains impurities having a concentration gradient such that a concentration becomes continuously lower toward the channel layer 5, and by patterning this silicon layer at a later process, source/drain layers made of a single layer structure may be formed which contains impurities having a concentration gradient such that a concentration becomes continuously lower toward the channel layer 5.

It is to be noted, here, although the first silicon layer a and the second silicon layer b containing n-type impurities are film-formed by the plasma CVD method, it is also allowable that after the first silicon layer a is film-formed in a state not containing n-type impurities, n-type impurities are introduced to the first silicon layer a by ion implantation, and thereafter, after the second silicon layer b is film-formed in a state not containing n-type impurities, n-type impurities whose concentrations are higher than that of the first silicon layer a are introduced into the second silicon layer a by ion implantation. However, when the control of a concentration of n-type impurities is taken into consideration, it is preferable that n-type impurities are introduced when film-formation is performed by the plasma CVD method.

Thereafter, as shown in FIG. 7(d), the second silicon layer b, the first silicon layer a, and the channel layer 5 which is a lower layer of the silicon layers, are patterned in an island shape through photolithography and etching processes. In this case, a contact hole (shown omitted) to the gate electrode 3 is formed.

Next, as shown in FIG. 8(e), a three-layer metal layer made of, e.g., titanium/aluminum/titanium is film-formed at film thicknesses of 50 nm/100 nm/50 nm in a state of covering the patterned second silicon layer b, the first silicon layer a, and the channel layer 5. Thereafter, the source electrode 9 and the drain electrode 10 made of the three-layer metal layer are formed through photolithography and etching processes. In this case, a space between the source electrode 9 and the drain electrode 10 are separated above a central portion of the gate electrode 3 above the channel layer 5, and in addition the second silicon layer b and the first silicon layer a are patterned and the source layer 7 and the drain layer 8 are formed. As a result, the source layer 7 becomes a state where the first silicon layer 7a and the second silicon layer 7b are laminated in this order, and the drain layer 8 becomes a state where the first silicon layer 8a and the second silicon layer 8b are laminated in this order. Further, in this etching, the channel protective layer 6 functions as an etching stopper layer.

Thereafter, as shown in FIG. 8(f), the passivation film 11 made of, e.g., a silicon nitride film, is formed at a film thickness of 200 nm, in a state of covering the whole area on the substrate 2 in this state. In succession, a contact hole (shown omitted) to the drain electrode 10 is formed.

Then, the next process is performed continuously in a case where a display device provided with the thin film transistor 1 of this type is manufactured. Namely, as shown in FIG. 6, the interlayer insulating film 21 covers the upper surface of the substrate 2 to which the thin film transistor 1 is provided, and the connection hole 21a connected to the thin film transistor 1 is formed to the interlayer insulating film 21. Thereafter, the lower electrode 23 connected to the thin film transistor 1 is pattern-formed on the interlayer insulating film 21 via the connection hole 21a. Next, after the periphery of the lower electrode 23 is covered with the insulating film pattern 24, the organic layer 25 including at least a light emitting layer is laminated and formed on the lower electrode 23 which is exposed from the insulating film pattern 24. Next, the upper electrode 26 is formed in a state of covering the organic layer 25 and the insulating film pattern 24. As a result, the organic EL element 22 connected to the thin film transistor 1 is formed by the lower electrode 23.

With the manufacture method of this type, it becomes possible to manufacture the thin film transistor 1 of the first embodiment and a display device using the thin film transistor.

### SECOND EMBODIMENT

### (Thin Film Transistor)

FIG. 9 is a cross sectional view for explaining a thin film transistor of a second embodiment. A thin film transistor 1′ shown in this drawing is a thin film transistor of a top gate type, and the source layer 7 and the drain layer 8 are provided by being laminated on the source electrode 9 and the drain electrode 10 which are pattern-formed on the substrate 2. Further, as characteristic structures in the present invention, the source/drain layers 7 and 8 contain impurities having a concentration gradient such that a concentration becomes lower toward the channel layer 5. Specifically, the source layer 7 has a two-layer structure constituted of the second silicon layer 7b covering the source electrode 9 and the first silicon layer 7a on the second silicon layer, and the drain layer 8 has a two-layer structure constituted of the second silicon layer 8b covering the drain electrode 10 and the first silicon layer 8a on the second silicon layer. Hence, the first silicon layers 7a and 8a containing n-type impurities at a concentration lower than that of the second silicon layers 7b and 8b are arranged at the channel layer 5 side.

Then, the channel layer 5 is provided in a state that both ends thereof are superimposed on end portions of this source layer 7 and the drain layer 8. Further, the gate electrode 3 is formed above this channel layer 5 via the gate insulating film 4. Furthermore, the passivation film 11 is provided at the whole surface area of the substrate 2 in this state.

Even if the thin film transistor 1′ has the structure of this type, as similar to the first embodiment, since the source/drain layers 7 and 8 have the two-layer structures arranging the first silicon layers 7a and 8a on the channel layer 5 side and the second silicon layers 7b and 8b on the side of the source/drain electrodes 9 and 10, it is possible to obtain effects similar to those of the thin film transistor 1 of the first embodiment.

It is to be noted, here, although description was made on an example that the source/drain layers 7 and 8 are configured by a two-layer structure constituted of the first silicon layers 7a and 8a and the second silicon layers 7b and 8b, the source/drain layers may be constituted of three or more layers or have a single layer structure if impurities having a concentration gradient in which a concentration becomes lower toward the channel layer 5 are contained, as similar to the first embodiment.

### (Display Device)

In addition, as the structure of a display device using the thin film transistor 1 of this type, the display device described by using FIG. 6 can be exemplified, and effects similar to those of the first embodiment can be obtained.

### (Manufacture Method)

Next, description will be made on a manufacture method for the thin film transistor 1′ having the structure described above and a manufacture method for a following display device.

First, the source electrode 9 and the drain electrode 10 are pattern-formed on the substrate 2.

Next, after a second silicon layer containing n-type impurities is film-formed, a first silicon layer containing impurities at a concentration lower than that of the second silicon layer is film-formed on the second silicon layer, by a plasma CVD method. Noted, film-formation of the second silicon layer and film-formation of the first silicon layer as above may be continuously performed, and in a case where this type of continuous film-formations are performed, film forming conditions may be controlled such that an impurity concentration continuously changes from the second silicon layer to the first silicon layer. As a result, the second silicon layer and the first silicon layer constituting source/drain layers, which are described later, become continuously laminated films. Thereafter, by patterning these, source/drain layers 7 and 8 are formed in which the second silicon layers 7b and 8b and the first silicon layers 7a and 8a are laminated in this order.

It is to be noted, here, although description was made on an example of film-forming of the first silicon layer and the second silicon layer in a state n-type impurities are included by the plasma CVD method, it has no problem even if the first silicon layer and the second silicon layer are film-formed in a state not containing n-type impurities, and after the film-formation, n-type impurities are introduced by ion implantation, as described in the first embodiment.

Subsequently, the channel layer 5 made of an amorphous silicon layer not containing impurities is formed in a state of covering the source layer 7 and the drain layer 8, and further the source electrode 10 and the drain electrode 11.

Next, the channel layer 5 is patterned into an island shape. As a result, it is shaped as both ends of the channel layer 5 are laminated on the source layer 7 and the drain layer 8. Thereafter, the gate insulating film 4 made of silicon oxide is formed in a state covering the channel layer 5, for example, by a plasma CVD method.

Next, the gate electrode 3 is pattern-formed above the channel layer 5 in a state that both ends are superimposed on the source layer 7 and the drain layer 8. Thereafter, the passivation film 11 is film-formed on the gate insulating film 4 in a state covering the gate electrode 3.

In the above manner, the thin film transistor 1′ of a top gate structure is formed.

Then, processes to follow in a case where a display device provided with the thin film transistor 1′ of this type is manufactured are assumed to be performed in a manner similar to processes described in the first embodiment.

By the above, it becomes possible to manufacture the thin film transistor 1′ of the second embodiment and the display device using the thin film transistor.

It is to be noted that although description was made about the thin film transistor of an n-channel type (n-type) in the above-described first embodiment and second embodiment, similar effects can be successfully obtained even in case of a thin film transistor of a p-channel type (p-type). In this case, p-type impurities constituted of boron or other III group elements are used.

1. A thin film transistor formed by laminating a gate electrode, a gate insulating film, a channel layer, and source/drain layers on a substrate in this order or in a reversed order thereof, characterized in that:
the source/drain layers are constituted of a silicon layer containing impurities such that a concentration becomes lower at the channel layer side than the other.

2. The thin film transistor as claimed in claim 1, characterized in that:
the source/drain layers are constituted of a silicon layer containing impurities having a concentration gradient such that a concentration becomes lower toward the channel layer.

3. The thin film transistor as claimed in claim 1, characterized in that:
the thin film transistor is an n-channel type.

4. The thin film transistor as claimed in claim 1, characterized in that:
the source/drain layers are formed of a silicon layer constituted of a plurality of layers containing impurities such that a concentration gradually becomes lower toward the channel layer.

5. The thin film transistor as claimed in claim 1, characterized in that:
the source/drain layers are constituted of a first silicon layer containing impurities and a second silicon layer containing impurities at a concentration higher than that of the first silicon layer; and
the first silicon layer is arranged to be at the channel layer side.

6. The thin film transistor as claimed in claim 5, characterized in that:
the first silicon layer is structured by a fine crystal silicon layer, and the second silicon layer is structured by an amorphous silicon layer.

7. A manufacture method for a thin film transistor formed by laminating a gate electrode, a gate insulating film, a channel layer, and source/drain layers on a substrate in this order or in a reversed order thereof, characterized in that:
characteristics of the thin film transistor are controlled by an impurity concentration of the source/drain layers.

8. The manufacture method for a thin film transistor characterized in that:
in the thin film transistor as claimed in claim 7, the source/drain layers are formed which are made of a silicon layer containing impurities such that a concentration becomes lower at a channel layer side than the other, in a process of forming the source/drain layers.

9. A display device in which a thin film transistor formed by laminating a gate electrode, a gate insulating film, a channel layer, and source/drain layers on a substrate in this order or in a reversed order thereof, and a display element connected to this thin film transistor are arrayed and formed on a substrate, characterized in that:
the source/drain layers are constituted of a silicon layer containing impurities such that a concentration becomes lower at a channel layer side than the other.
